(19) United States
(12) Patent Application Publication
(10) Pub. No.: US 2026/0255835 A1
(43) Pub. Date: Aug. 27, 2026

(54) DISPLAY DEVICE

(71) Applicant: LG Display Co., Ltd., Seoul (KR)

(72) Inventors: Byung-Gwan Hyun, Paju-si (KR); Seung-Bum Lee, Paju-si (KR); Won-Rae Kim, Paju-si (KR); Jung-Min Yoon, Paju-si (KR)

(21) Appl. No.: 19/409,860

(22) Filed: Dec. 5, 2025

(30) Foreign Application Priority Data
Feb. 27, 2025 (KR) 10-2025-0025769

(51) Int. Cl. H10K 59/38; H10K 59/121; H10K 59/122; H10K 59/80; H10D 86/40; H10D 86/60; H10K 102/00

(52) U.S. Cl. CPC H10K 59/38; H10K 59/1213; H10K 59/122; H10K 59/877; H10K 59/8792; H10D 86/423; H10D 86/60; H10K 2102/331

(57) ABSTRACT

A display device offering increased luminance at peripheral viewing angles and increased color purity without loss of luminance at a perpendicular viewing angle is provided. A bilayered color filter makes these improvements possible while eliminating the need for a polarizing plate to reduce glare. In particular, a color filter layer can correspond to the emission area of each pixel, the color filter layer including a first color filter pattern layer and a second color filter pattern layer on the first color filter pattern layer, in which one of the first and second color filter patterns includes a first color particle having a first size, and the other one of the first and second color filter patterns includes a second color particle having a second size, and wherein the second size is greater than the first size.

### CROSS REFERENCE TO RELATED APPLICATION

This application claims priority from and the benefit of Korean Patent Application No. 10-2025-0025769, filed on February 27, 2025, which is hereby incorporated by reference for all purposes as if fully set forth herein.

### BACKGROUND

### FIELD

Embodiments of the invention relate generally to a display device, and, more particularly, to a display device that is capable of preventing display quality degradation and improving luminance in a side viewing angle.

### DISCUSSION OF THE BACKGROUND

Display devices, such as a television (TV), a monitor, a smartphone, a tablet PC, or a laptop, display images in a variety of formats and forms.

The display device in all of these formats typically includes a display panel with either a plurality of light emitting elements or a liquid crystal for displaying images and transistors for controlling the operation of the light emitting elements or the liquid crystal. The display device displays the desired image through the light emitting elements or the liquid crystal.

A light emitting display technology, which includes a light emitting diode, is rapidly developing. The light emitting display device can be categorized as an organic light emitting display device, which uses an organic emitting material, or an inorganic light emitting display, which uses an inorganic emitting material.

To minimize external light reflection (e.g., ambient light reflection), conventional light emitting display devices typically include a polarizing plate on the display surface. However, this introduces a number of disadvantages. Polarizing plates can reduce the sharpness of the display and can to some extent distort the image. Surface irregularities on the polarizing plate can generate sparkling and cause further image distortion. In the case of liquid crystal displays requiring backlighting, brightness can be reduced by a polarizing plate, and this can negatively affect efforts to maximize image quality. Also, even though polarizing plates are added in order to minimize external light reflection, they can scatter external light and thereby still cause significant glare. This, in turn, can cause eyestrain.

Another limitation that many display screens have is a limited viewing angle. This is a special problem in public areas where clear visibility for signage is important and in situations such as car dashboard displays or medical displays, where viewing the screens from various angles to perceive critical information is important. When viewed at angles outside of an optimal range, displays can exhibit distorted images, a less accurate portrayal of colors and/or a loss of brightness or optimal contrast.

There is a need in the art to reduce or eliminate glare for observers watching display screens without the disadvantages of employing a polarizing plate. Consumers would also welcome improvement in image quality, including better color fidelity, higher brightness and better contrast, at peripheral screen angles.

The above information disclosed in this Background section is only for understanding of the background of the inventive concepts, and, therefore, it may contain information that does not constitute prior art.

### SUMMARY

The present disclosure is directed to a display device that substantially obviates one or more of the problems associated with the limitations and disadvantages of the related conventional art.

An object of the present disclosure is to provide a display device being capable of preventing display quality degradation and improving luminance in a side viewing angle.

Another object of the present disclosure is to provide a display device that is capable of improving a viewing angle by using a color filter layer in the construction of its display screen.

Another object of the present disclosure is to provide a display device that is capable of minimizing a luminance decrease in a front viewing angle while improving viewing quality from wide viewing angles.

Additional features of the inventive concepts will be set forth in the description which follows, and in part will be apparent from the description, or may be learned by practice of the inventive concepts.

A display device according to an embodiment includes a substrate including a pixel region, the pixel region including an emission area and a non-emission area; a planarization layer covering the substrate; a light emitting diode on the planarization layer and in the pixel region; a buffer layer on the light emitting diode; a black matrix disposed on the buffer layer and corresponding to the non-emission area; and a color filter layer disposed on the buffer layer and corresponding to the emission area, the color filter layer including a first color filter pattern layer and a second color filter pattern layer on the first color filter pattern layer, in which one of the first and second color filter pattern layers includes a first color particle having a first size, and the other one of the first and second color filter pattern layers includes a second color particle having a second size, and the second size is greater than the first size.

The first size of the first color particle may be in a range of from 1 nm to 80 nm, and the second size of the second color particle may be in a range of from 80 nm to 200 nm.

The second color filter pattern layer may include the second color particle.

The display device may further include a scattering layer that may include a scattering particle and may be disposed on a side surface of the black matrix.

The scattering particle may have a third size that may be equal to or greater than the second size. The third size may be in a range of from 200 nm to 300 nm.

The second color filter pattern layer may cover the scattering layer.

The first color filter pattern layer may have a first thickness, and the second color filter pattern layer may have a second thickness that may be smaller than the first thickness.

The first color filter pattern layer and the black matrix may have the same thickness.

The second color filter pattern layer may have an area that is larger than that of the first color filter pattern layer.

The second color filter pattern layer may cover the black matrix.

The pixel region may include a first pixel region and a second pixel region that is adjacent to the first pixel region, and the second color filter pattern layer in the first pixel region may extend into the non-emission area of the second pixel region.

The second color filter pattern layer in the first pixel region may have a blue color filter pattern.

The second color filter pattern layer in the first pixel region may cover at least a portion of the black matrix in the non-emission area of the second pixel region.

The second color filter pattern layer in the first pixel region may cover at least a portion of the black matrix in the non-emission area of the second pixel region.

An area of the first color filter pattern layer in the first pixel region may be the same as an area of the first color filter pattern layer in the second pixel region, and an area of the second color filter pattern layer in the first pixel region may be greater than an area of the second color filter pattern layer in the second pixel region.

The display device may further include a pixel definition layer disposed on the planarization layer and corresponding to the non-emission area, in which the pixel definition layer may have a light-absorbing property.

The pixel definition layer may include an opening in correspondence to the emission area, in which an area of the color filter layer may be greater than an area of the opening.

The display device may further include a first thin film transistor disposed between the substrate and the planarization layer and including a first semiconductor layer, and a second thin film transistor disposed between the substrate and the planarization layer and including a second semiconductor layer.

The first semiconductor layer may include an oxide semiconductor material.

The first thin film transistor may be a driving thin film transistor electrically connected to the light emitting diode.

A color filter for modifying light emitted from a monochromatic light source according to another embodiment includes a first particle layer including pigment particles in a first size range, and a second particle layer including pigment particles in a second size range, in which the second particle layer is on the first particle layer, the first size range is substantially different from the second size range, the first size range does not fully include the second size range, and the second size range does not fully include the first size range.

The particles in the first size range may be larger than the particles in the second size range. The particles in the first size range may be smaller than the particles in the second size range.

The color filter may include a plurality of color filter areas that are detached from each other, the plurality of color filter areas corresponding to a parallel plurality of light emitting areas, the plurality of light emitting areas each emitting monochromatic light of the same color.

The first size range may be from about 1 nm to about 80 nm, and the second size range may be from about 80 nm to about 200 nm.

A color filter system may include three color filters, each having a plurality of color filter areas as described above, each color filter being designed to modify monochromatic light having a wavelength different from the wavelengths of monochromatic light modified by the other color filters.

The three color filters may modify red, green and blue wavelengths of light, respectively.

Each color filter area of a color filter may be disposed adjacent to a color filter area of each of the other two color filters, forming a color display area of a display device.

A layer of transparent or white scattering particles may be disposed in contact with an edge of each color filter area.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic view illustrating an organic light emitting display device according to an embodiment of the present disclosure.

FIG. 2 is a schematic circuit diagram of an organic light emitting display device according to an embodiment of the present disclosure.

FIG. 3 is a schematic cross-sectional view illustrating an organic light emitting display device according to a first embodiment of the present disclosure.

FIG. 4 is a schematic cross-sectional view illustrating an organic light emitting display device according to a second embodiment of the present disclosure.

FIG. 5 is a schematic cross-sectional view illustrating an organic light emitting display device according to a third embodiment of the present disclosure.

FIG. 6 is a schematic an organic light emitting view illustrating a light emitting display device according to a fourth embodiment of the present disclosure.

FIG. 7 is a schematic exploded perspective view of a display module according to an embodiment of the present disclosure.

FIG. 8 is a schematic cross-sectional view of a display module according to an embodiment of the present disclosure.

FIG. 9 is a schematic plan view of a display module according to an embodiment of the present disclosure.

FIG. 10 is a graph showing a reflectance, a luminance in a front viewing angle and a luminance in a side viewing angle, where the color filter layer features relatively small particles (50 nm) in a single layer (case 1), relatively large particles (100 nm) in a single layer (case 2) and two particle layers including relatively small particles (50 nm) in a first (lower) layer and relatively large particles (100 nm) in a second (upper) layer (case 3).

### DETAILED DESCRIPTION

The present description details a new display screen structure that meets the need in the art for improved image quality without the disadvantages of using a polarizing plate to address glare and meets the need in the art for improved image quality at peripheral viewing angles.

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

Reference will now be made in detail to aspects of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to those skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscures the subject matter of the present disclosure, the detailed description thereof can be omitted. When 'including', 'having', 'consisting', and the like are used in this specification, other parts may be added unless 'only' is used. When a component is expressed in the singular, cases including the plural are included unless specific statement is described.

The expression "at least one of a, b, and c" described throughout the specification can encompass 'a alone', 'b alone', 'c alone', 'a and b', 'a and c', 'b and c', or 'all of a, b, and c'. The advantages and features of the present invention, and the methods for achieving them, will become apparent by referring to the embodiments described in detail below together with the accompanying drawings.

In construing an element, the element is construed as including an error or tolerance range although there is no explicit description of such an error or tolerance range.

In describing a time relationship, for example, when the temporal order is described as, for example, “after,” “subsequent,” “next,” and “before,” a case that is not continuous may be included unless a more limiting term, such as “just,” “immediate(ly),” or “direct(ly)” is used.

The area, length, or thickness of each component described in the specification is illustrated for convenience of explanation, and the present invention is not necessarily limited to the area and thickness of the illustrated component.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in co-dependent relationship.

Without specific description, a transistor constituting the pixel circuit of the present disclosure may include at least one of an oxide thin film transistor (Oxide TFT), an amorphous silicon TFT (a-Si TFT), and a low temperature poly silicon (LTPS) TFT.

The following embodiments are described with reference to organic light emitting display devices. However, the embodiment of the present disclosure is not limited to organic light emitting display devices. For example, a display device according to an embodiment of the present disclosure may be an organic light emitting display device using an organic light emitting material, an inorganic light emitting display device using an inorganic light emitting material such as a quantum dot, or a micro-LED display device. Namely, the light emitting diode display device of the present disclosure may be an organic light emitting display device, an inorganic light emitting display device, or a micro-LED display device.

Reference will now be made in detail to some of the examples and preferred embodiments, which are illustrated in the accompanying drawings.

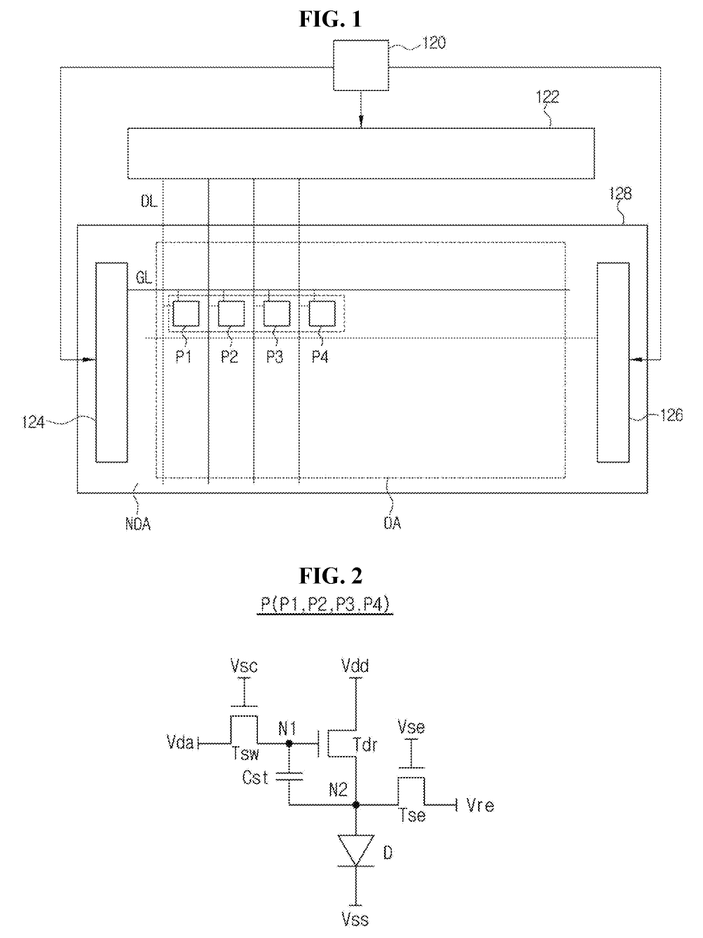

FIG. 1 is a schematic view illustrating an organic light emitting display device according to an embodiment of the present disclosure.

As shown in FIG. 1, an organic light emitting display device according to an embodiment of the present disclosure includes a timing controlling unit 120 (e.g., a circuit), a data driving unit 122 (e.g., a circuit), first and second gate driving units 124 and 126 (e.g., circuits) and a display panel 128.

The timing controlling unit 120 generates an image data RGB according to an additive color model in which components representing the intensities of red, green and blue light combine to form a color image, a data control signal and a gate control signal using an image signal and a plurality of timing signals including a data enable signal, a horizontal synchronization signal, a vertical synchronization signal and a clock signal transmitted from an external system such as a graphic card or a television system. The timing controlling unit 120 transmits the image data and the data control signal to the data driving unit 122, and transmits the gate control signal to the first and second gate driving units 124 and 126.

The data driving unit 122 generates a data signal (a data voltage) Vda (of FIG. 2) using the image data and the data control signal transmitted from the timing controlling unit 120 and transmits the data signal Vda to a data line DL of the display panel 128.

The first and second gate driving units 124 and 126 generate a gate signal (a gate voltage) Vsc and Vse (of FIG. 2) using the gate control signal transmitted from the timing controlling unit 120 and applies the gate signal Vsc and Vse to a gate line GL of the display panel 128.

The first and second gate driving units 124 and 126 may have a gate in panel (GIP) type to be formed in a non-display area NDA of a substrate of the display panel 128 having the gate line GL, the data line DL and a pixel region P.

Although the first and second gate driving units 124 and 126 are disposed in both side portions of the display panel 128 in the embodiment of FIG. 1, one gate driving unit may be disposed in one side portion of the display panel 128 in another embodiment.

The display panel 128 includes a display area DA at a central portion thereof and a non-display area NDA surrounding the display area DA. The display panel 128 displays an image using the gate signal Vsc and Vse and the data signal Vda. For displaying an image, the display panel 128 includes a plurality of pixel regions P, a plurality of gate lines GL and a plurality of data lines DL in the display area DA.

The gate line GL and the data line DL cross each other to define the first, second, third and fourth pixel regions P1, P2, P3 and P4. For example, the first, second, third and fourth pixel regions P1, P2, P3 and P4 may correspond to red, green, blue and white colors, respectively.

Each of the first, second, third and fourth pixel regions P1, P2, P3 and P4 may include a plurality of transistors such as a switching transistor Tsw (of FIG. 2), a driving transistor Tdr (of FIG. 2) and a sensing transistor Tse (of FIG. 2), a storage capacitor Cst (of FIG. 2) and a light emitting diode D (of FIG. 2).

FIG. 2 is a schematic circuit diagram of an organic light emitting display device according to an embodiment of the present disclosure.

Referring to FIG. 2 with FIG. 1, each of the first, second, third and fourth pixel regions P1, P2, P3 and P4 of the light emitting display device according to an embodiment of the present disclosure includes a switching transistor Tsw, a driving transistor Tdr, a sensing transistor Tse, a storage capacitor Cst and a light emitting diode D.

Although each of the first, second, third and fourth pixel regions P1, P2, P3 and P4 has a 3T1C structure having three transistors and one storage capacitor in the embodiment of FIG. 2, each of the first, second, third and fourth pixel regions P1, P2, P3 and P4 may have one of a 6T1C structure having six transistors and one storage capacitor, a 7T1C structure having seven transistors and one storage capacitor and a 8T1C structure having eight transistors and one storage capacitor in other embodiments.

Although the switching transistor Tsw, the driving transistor Tdr and the sensing transistor Tse may have a negative type (N type) in the embodiment of FIG. 2, at least one of the switching transistor Tsw, the driving transistor Tdr and the sensing transistor Tse may have a positive type (P type) in another embodiment.

The switching transistor Tsw is switched according to a scan signal Vsc to transmit a data signal Vda to a first node N1.

A gate electrode of the switching transistor Tsw is connected to the gate line GL to receive the scan signal Vsc, a drain electrode of the switching transistor Tsw is connected to the data line DL to receive the data signal Vda, and a source electrode of the switching transistor Tsw is connected to the first node N1.

The driving transistor Tdr is switched according to a voltage of the first node N1 to transmit a high level signal (high level voltage) Vdd to a second node N2.

A gate electrode of the driving transistor Tdr is connected to the first node N1, a drain electrode of the driving transistor Tdr is connected to a high level power line to receive the high level signal Vdd, and a source electrode of the driving transistor Tdr is connected to the second node N2.

Each of the source electrode of the switching transistor Tsw and the source electrode of the driving transistor Tdr acts as an input terminal, and each of the drain electrode of the switching transistor Tsw and the drain electrode of the driving transistor Tdr acts as an output terminal.

The sensing transistor Tse is switched according to a sensing signal (sensing voltage) Vse to transmit a reference signal (reference voltage) Vre to the second node N2 or transmit a voltage of the second node N2 to a reference line.

A gate electrode of the sensing transistor Tse is connected to the gate line GL to receive the sensing signal Vse, a drain electrode of the sensing transistor Tse is connected to the reference line to receive the reference signal Vre or transmit a voltage of the second node N2 to the reference line, and a source electrode of the sensing transistor Tse is connected to the second node N2.

The storage capacitor Cst keeps the data signal Vda supplied to the first node N1 for one frame and stores a threshold voltage Vth of the driving transistor Tdr.

A first capacitor electrode of the storage capacitor Cst is connected to the first node N1, and a second capacitor electrode of the storage capacitor Cst is connected to the second node N2.

The light emitting diode D emits a light of a luminance proportional to a current of the driving transistor Tdr.

An anode of the light emitting diode D is connected to the second node N2, and a cathode of the light emitting diode D is connected to a low level power line to receive a low level signal (low level voltage) Vss.

The source electrode of the switching transistor Tsw, the gate electrode of the driving transistor Tdr and the first capacitor electrode of the storage capacitor Cst constitute the first node N1, and the source electrode of the driving transistor Tdr, the source electrode of the sensing transistor Tse, the second capacitor electrode of the storage capacitor Cst and anode of the light emitting diode D constitute the second node N2.

The light emitting diode D may display an image having a luminance corresponding to the image data RGB according to a driving of pixel circuits of the first, second, third and fourth pixel regions P1, P2, P3 and P4.

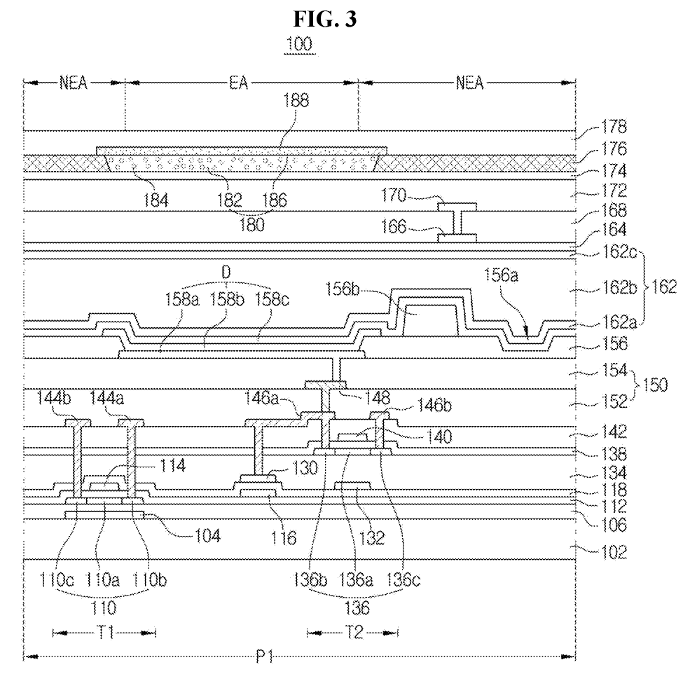

FIG. 3 is a schematic cross-sectional view illustrating an organic light emitting display device according to a first embodiment of the present disclosure.

As shown in FIG. 3, the organic light emitting display device 100 includes a substrate 102, a thin film transistor (TFT) on the substrate 102, a planarization layer 150 covering the TFT, an organic light emitting diode (OLED) D on the planarization layer 150, a black matrix 176 disposed over the OLED D and corresponding to a boundary of a pixel region P and a color filter layer 180 disposed over and corresponding to the OLED D.

A plurality of pixel regions P are defined on the substrate 102. The substrate 102 may be a glass substrate or a plastic substrate. For example, the substrate 102 may be one of a polyimide (PI) substrate, a polyethersulfone (PES) substrate, a polyethylenenaphthalate (PEN) substrate, a polyethylene terephthalate (PET) substrate and a polycarbonate (PC) substrate.

In an embodiment of the present disclosure, the substrate 102 may have a triple-layered structure including a first polyimide (PI) layer, a second PI layer and an interlayer inorganic layer between the first and second PI layers.

A first light shielding pattern 104 is disposed on the substrate 102. The light through the substrate 102 can be blocked by the first light shielding pattern 104. For example, the first light shielding pattern 104 may be formed of a metallic material, e.g., molybdenum (Mo), aluminum (Al), chromium (Cr), gold (Au), titanium (Ti), nickel (Ni), neodymium (Nd), copper (Cu) or their alloy, and have a single-layered structure or a multi-layered structure.

A first buffer layer 106 covering the first light shielding pattern 104 is disposed over the substrate 102. The moisture and/or oxygen can be blocked by the first buffer layer 106. For example, the first buffer layer 106 may be formed of an inorganic insulating material, e.g., silicon oxide or silicon nitride, and have a single-layered structure or a multi-layered structure. When the first light shielding pattern 104 is omitted, the first buffer layer 106 may be directly formed on the substrate 102 and contact the substrate 102.

A first semiconductor layer 110 corresponding to the first light shielding pattern 104 is disposed on the first buffer layer 106. The first semiconductor layer 110 may include one of a poly-semiconductor material, an amorphous semiconductor material and an oxide semiconductor material. When the first light shielding pattern 104 and the first buffer layer 106 are omitted, the first semiconductor layer 110 may be directly disposed on the substrate 102.

In an exemplary embodiment of the present disclosure, the first semiconductor layer 110 may be formed of a poly-semiconductor material, e.g., polycrystalline silicon. The first semiconductor layer 110 may include a first channel region 110a, a first source region 110b at one side of the first channel region 110a and a first drain region 110c at the other side of the first channel region 110a. Impurities may be doped into the first source and drain regions 110b and 110c.

A first gate insulating layer 112 covering the first semiconductor layer 110 is disposed over the first buffer layer 106. The first gate insulating layer 112 may be formed of an inorganic insulating material, e.g., silicon oxide or silicon nitride, and have a single-layered structure or a multi-layered structure.

A first gate electrode 114 corresponding to the first channel region 110a of the first semiconductor layer 110 is disposed on the first gate insulating layer 112. In addition, a first capacitor electrode 116, which is spaced apart from the first gate electrode 114, is disposed on the first gate insulating layer 112.

The first gate electrode 114 and the first capacitor electrode 116 may be disposed on the same layer and be formed of the same material. For example, each of the first gate electrode 114 and the first capacitor electrode 116 may be formed of a metallic material, e.g., Mo, Al, Cr, Au, Ti, Ni, Nd, Cu or their alloy, and have a single-layered structure or a multi-layered structure.

A first interlayer insulating layer 118 covering the first gate electrode 114 and the first capacitor electrode 116 is disposed on the first gate insulating layer 112. The first interlayer insulating layer 118 may be formed of an inorganic insulating material, e.g., silicon oxide or silicon nitride, and have a single-layered structure or a multi-layered structure.

A second capacitor electrode 130 corresponding to the first capacitor electrode 116 and a second light shielding pattern 132 spaced apart from the second capacitor electrode 130 are disposed on the first interlayer insulating layer 118.

The second capacitor electrode 130 and the second light shielding pattern 132 may be disposed on the same layer and be formed of the same material. For example, each of the second capacitor electrode 130 and the second light shielding pattern 132 may be formed of a metallic material, e.g., Mo, Al, Cr, Au, Ti, Ni, Nd, Cu or their alloy, and have a single-layered structure or a multi-layered structure.

A second interlayer insulating layer 134 covering the second capacitor electrode 130 and the second light shielding pattern 132 is disposed on the first interlayer insulating layer 118. The external moisture and/or oxygen can be blocked by the second interlayer insulating layer 134. For example, the second interlayer insulating layer 134 may be formed of an inorganic insulating material, e.g., silicon oxide or silicon nitride, or an organic insulating material, e.g., photo-acryl (polymers formed from photo-crosslinkable acrylic monomers) or benzocyclobutene (BCB), and have a single-layered structure or a multi-layered structure.

A second semiconductor layer 136 corresponding to the second light shielding pattern 132 is disposed on the second interlayer insulating layer 134. The second semiconductor layer 136 may include one of a poly-semiconductor material, an amorphous semiconductor material and an oxide semiconductor material.

In an exemplary embodiment of the present disclosure, the second semiconductor layer 136 may be formed of an oxide semiconductor material, e.g., indium-gallium-zinc oxide (IGZO), zinc oxide (ZnO), tin oxide (SnO2), copper oxide (Cu2O), nickel oxide (NiO), indium-tin-zinc oxide (ITZO) or indium-aluminum-zinc oxide (IAZO).

The second semiconductor layer 136 may include a second channel region 136a, a second source region 136b at one side of the second channel region 136a and a second drain region 136c at the other side of the second channel region 136a. Impurities may be doped into the second source and drain regions 136b and 136c.

A second gate insulating layer 138 covering the second semiconductor layer 136 is disposed over the second interlayer insulating layer 134. The second gate insulating layer 138 may be formed of an inorganic insulating material, e.g., silicon oxide or silicon nitride, and have a single-layered structure or a multi-layered structure.

A second gate electrode 140 corresponding to the second channel region 136a of the second semiconductor layer 136 is disposed on the second gate insulating layer 138. For example, the second gate electrode 140 may be formed of a metallic material, e.g., Mo, Al, Cr, Au, Ti, Ni, Nd, Cu or their alloy, and have a single-layered structure or a multi-layered structure.

A third interlayer insulating layer 142 covering the second gate electrode 140 is disposed on the second gate insulating layer 138. The third interlayer insulating layer 142 may be formed of an inorganic insulating material, e.g., silicon oxide or silicon nitride, and have a single-layered structure or a multi-layered structure.

A first source electrode 144a, a first drain electrode 144b, a second source electrode 146a and a second drain electrode 146b are disposed on the third interlayer insulating layer 142.

The first source electrode 144a and the first drain electrode 144b are respectively connected to the first source region 110b and the first drain region 110c via contact holes through the third interlayer insulating layer 142, the second gate insulating layer 138, the second interlayer insulating layer 134, the first interlayer insulating layer 118 and the first gate insulating layer 112. The first source electrode 144a is connected to the first capacitor electrode 116 via a contact hole through the third interlayer insulating layer 142, the second gate insulating layer 138, the second interlayer insulating layer 134 and the first interlayer insulating layer 118.

The second source electrode 146a and the second drain electrode 146b are respectively connected to the second source region 136b and the second drain region 136c via contact holes through the third interlayer insulating layer 142 and the second gate insulating layer 138. The second source electrode 146a is connected to the second capacitor electrode 130 via a contact hole through the third interlayer insulating layer 142, the second gate insulating layer 138 and the second interlayer insulating layer 134.

The first source and drain electrodes 144a and 144b and the second source and drain electrodes 146a and 146b may be disposed on the same layer and formed of the same material. For example, each of the first source and drain electrodes 144a and 144b and the second source and drain electrodes 146a and 146b may be formed of a metallic material, e.g., Mo, Al, Cr, Au, Ti, Ni, Nd, Cu or their alloy, and have a single-layered structure or a multi-layered structure.

The first semiconductor layer 110, the first gate electrode 114, the first source electrode 144a and the first drain electrode 144b constitute a first TFT T1, and the second semiconductor layer 136, the second gate electrode 140, the second source electrode 146a and the second drain electrode 146b constitute a second TFT T2. For example, the first TFT T1 may be a switching TFT, and the second TFT2 may be a driving TFT. In addition, the first and second capacitor electrodes 116 and 130 constitute a storage capacitor.

The organic light emitting display device of the present disclosure includes the first and second TFTs T1 and T2. Each of the first semiconductor layer 110 of the first TFT T1 and the second semiconductor layer 136 of the second TFT T2 may include one of a poly-semiconductor material, an amorphous semiconductor material and an oxide semiconductor material, and at least one of the first semiconductor layer 110 of the first TFT T1 and the second semiconductor layer 136 of the second TFT T2 may include the oxide semiconductor material. In an exemplary embodiment of the present disclosure, the first semiconductor layer 110 of the first TFT T1 may be formed of the poly-semiconductor material, e.g., polycrystalline silicon, and the second semiconductor layer 136 of the second TFT T2 may be formed of the oxide semiconductor material.

In FIG. 3, the first gate electrode 114, the first source electrode 144a and first drain electrode 144b are disposed over the first semiconductor layer 110, and the second gate electrode 140, the second source electrode 146a and the second drain electrode 146b are disposed over the second semiconductor layer 136. Namely, each of the first and second TFTs T1 and T2 has a coplanar structure. Alternatively, in each of the first and second TFTs T1 and T2, a gate electrode may be disposed under a semiconductor layer, and a source and a drain electrode may be disposed over the semiconductor layer. Namely, each of the TFTs T1 and T2 may have an inverted-staggered structure.

A planarization layer 150 covering the first source and drain electrodes 144a and 144b and the second source and drain electrodes 146a and 146b is disposed on the third interlayer insulating layer 142. The planarization layer 150 may be formed of an organic insulating material, e.g., photo-acryl (polymers formed from photo-crosslinkable organic aromatic materials) or BCB.

The planarization layer 150 may include a first planarization layer 152 on the first source and drain electrodes 144a and 144b and the second source and drain electrodes 146a and 146b and a second planarization layer 154 on the first planarization layer 152. The planarization layer 150 may further include a third planarization layer on the second planarization layer 154 to have a triple-layered structure.

A connection electrode 148 corresponding to the second source electrode 146a is disposed on the first planarization layer 152, and the second planarization layer 154 covering the connection electrode 148 is disposed on the first planarization layer 152.

The connection electrode 148 may be connected to the second source electrode 146a through a contact hole in the first planarization layer 152. For example, the connection electrode 148 may be formed of a metallic material, e.g., Mo, Al, Cr, Au, Ti, Ni, Nd, Cu or their alloy, and have a single-layered structure or a multi-layered structure.

A first electrode 158a is disposed on the second planarization layer 154. The first electrode 158a corresponds to the connection electrode 148 and is connected to the connection electrode 148 through a contact hole in the second planarization layer 154.

For example, the first electrode 158a is separately formed in each pixel region P. The first electrode 158a may be an anode and may include a transparent conductive oxide (TCO) layer, which is formed of a conductive material, e.g., a transparent conductive oxide material, having a relatively high work function, and a reflective layer.

For example, the transparent conductive oxide material may include at least one of indium-tin-oxide (ITO), indium-zinc-oxide (IZO), indium-tin-zinc oxide (ITZO), tin oxide (SnO), zinc oxide (ZnO), indium-copper-oxide (ICO) and aluminum-zinc-oxide (Al:ZnO, AZO), and the reflective layer may include at least one of silver (Ag), an alloy of Ag and one of palladium (Pd), Cu, In and Nd and aluminum-palladium-copper alloy (APC). For example, the first electrode 158a may have a double-layered structure of Ag/ITO or APC/ITO or a triple-layered structure of ITO/Ag/ITO or ITO/APC/ITO.

A pixel definition layer (e.g., a bank) 156 is formed on the second planarization layer 154 at a boundary of the pixel region P. The pixel definition layer 156 covers an edge of the first electrode 158a and has an opening to expose a center of the first electrode 158a. Namely, the opening of the pixel definition layer 156 exposes the first electrode 158a in an emission area EA.

The pixel definition layer 156 may have a light-absorbing property. The pixel definition layer 156 may be a black pixel definition layer or a gray pixel definition layer. The pixel definition layer 156 may include a black particle, e.g., a light-absorbing particle, disposed in an organic material, e.g., a binder. For example, the organic material may be at least one of photo-acryl, benzocyclobutene and polyimide, and the black particle may be at least one of carbon black, carbon nano tube (CNT) and graphene.

The pixel definition layer 156 is partially removed to form a trench 156a. A length of a current path is increased by the trench 156a so that a current leakage into adjacent pixel region P can be prevented.

In addition, a spacer 156b is disposed on the pixel definition layer 156. The spacer 156b may have a taper shape or a reverse-taper shape. For example, the spacer 156b may be formed of an organic insulating material, e.g., photo-acryl or BCB, and may have a single-layered structure or a multi-layered structure.

An organic light emitting layer 158b covers the first electrode 158a, its edges covering the pixel definition layer 156, upon which the spacer 156b is disposed. The organic light emitting layer 158b contacts the first electrode 158a in the opening of the pixel definition layer 156.

The organic light emitting layer 158b may include an organic emitting material layer (EML) including a host and a dopant. In addition, the organic light emitting layer 158b may further include at least one of a hole injection layer (HIL), a hole transporting layer (HTL), an electron blocking layer (EBL), a hole blocking layer (HBL), an electron transporting layer (ETL) and an electron injection layer (EIL) and have a multi-layered structure. In addition, the organic light emitting layer 158b may include two or more emitting parts and a charge generation layer therebetween, forming a tandem structure.

A second electrode 158c is formed over the substrate 102 where the organic light emitting layer 158b is formed. The second electrode 158c covers an entire surface of the display area. The second electrode 158c may be formed of at least one of ITO, IZO, Al, Ag, Cu, Pb, magnesium (Mg), Mo, Ti and an alloy thereof and have a single-layered structure or a multi-layered structure. The second electrode 158c may have a thin profile (small thickness) to provide a light transmittance property (or a semi-transmittance property).

The first electrode 158a, the organic light emitting layer 158b and the second electrode 158c constitute an organic light emitting diode D. The organic light emitting diode D may emit red, green and blue light in the red, green and blue pixel regions, respectively. Alternatively, the organic light emitting diode D may emit red, green, blue and a combination of red, green and blue light in the red, green, blue and white pixel regions, respectively.

In the organic light emitting display device 100, the light from the light emitting layer 158b passes through the second electrode 158c and a color filter layer 180 to display an image. Namely, the organic light emitting display device 100 of the present disclosure is a top-emission type display device.

An encapsulation layer (or encapsulation film) 162 is formed on the second electrode 158c to prevent penetration of moisture into the organic light emitting diode D. The encapsulation layer 162 may cover an entire substrate 102. The encapsulation layer 162 includes a first inorganic insulating layer 162a, an organic insulating layer 162b and a second inorganic insulating layer 162c sequentially stacked.

Each of the first and second inorganic insulating layers 162a and 162c may be formed of an inorganic insulating material, e.g., silicon oxide or silicon nitride. The organic insulating layer 162b may be formed of an organic insulating material, e.g., acryl resin, epoxy resin, phenolic resin, polyamide resin or polyimide resin.

A second buffer layer 164 is disposed on the encapsulation layer 162 and over an entire surface of the substrate 102. Moisture and/or oxygen can be blocked by the second buffer layer 164. For example, the second buffer layer 164 may be formed of an inorganic insulating material, e.g., silicon oxide or silicon nitride, and have a single-layered structure or a multi-layered structure.

A bridge pattern 166 is disposed on the second buffer layer 164, and a fourth interlayer insulating layer 168 is disposed on the bridge pattern 166 and over an entire surface of the substrate 102. For example, the fourth interlayer insulating layer 168 may be formed of an inorganic insulating material, e.g., silicon oxide or silicon nitride, or an organic insulating material, e.g., photo-acryl or BCB, and have a single-layered structure or a multi-layered structure.

A sensor pattern 170 is disposed on the fourth interlayer insulating layer 168. The sensor pattern 170 is connected to the bridge pattern 166 through a contact hole in the fourth interlayer insulating layer 168.

For example, each of the bridge pattern 166 and the sensor pattern 170 may be formed of one of ITO, IZO, Al, Ag, Cu, Pb, Mg, Mo, Ti and their alloys and may have a single-layered structure or a multi-layered structure.

A first protection layer 172 is disposed over an entire surface of the substrate 102 to cover the sensor pattern 170. The first protection layer 172 may be formed of an inorganic insulating material, e.g., silicon oxide or silicon nitride, or an organic insulating material, e.g., photo-acryl or BCB, and may have a single-layered structure or a multi-layered structure.

A third buffer layer 174 is disposed on the first protection layer 172 and over an entire surface of the substrate 102. The third buffer layer 174 may be formed of an inorganic insulating material, e.g., silicon oxide or silico nitride, and may have a single-layered structure or a multi-layered structure.

A black matrix 176 is disposed on the third buffer layer 174. The black matrix 176 is positioned at a boundary of the pixel region P and includes an opening that corresponds to the organic light emitting diode D. Namely, the black matrix 176 is positioned in a non-emission area NEA. The opening of the black matrix 176 corresponds to the opening of the pixel definition layer 156.

For example, the black matrix 176 may include black particles, e.g., carbon black, CNT or graphene.

A size (e.g., a planar area) of the opening in the black matrix 176 may be greater than that of the opening in the pixel definition layer 156. When an opening of the black matrix 176 is equal to or smaller than an opening of the pixel definition layer 156, a viewing angle of the organic light emitting display device 100 may be decreased.

A color filter layer 180 corresponding to the black matrix 176 is disposed on the third buffer layer 174. An area (e.g., a planar area) of the color filter layer 180 may be greater than that of the opening of the pixel definition layer 156. The color filter layer 180 may include a red color filter corresponding to the red pixel region, a green color filter corresponding to the green pixel region and a blue color filter corresponding to the blue pixel region.

The color filter layer 180 includes a first color filter pattern layer 182 and a second color filter pattern layer 186 on the first color filter pattern layer 182. Thus, the color filter layer 180 may have a double-layered structure.

The first color filter pattern layer 182 includes first color particles 184 having a first size (e.g., a diameter), and the second color filter pattern layer 186 includes second color particles 188 having a second size that is smaller than the first size. The first size may be in a range of from 80nm to 200nm, and the second size may be in a range of from 1nm to 80nm. Each of the first and second color particles 184 and 188 may be a pigment.

The color particles having absorbance provide high color purity with a relatively small particle size and a high scattering property with a relatively large particle size. Accordingly, the external light (e.g., the ambient light) is scattered by the first color particles 184 to minimize the external light reflection and increase luminance (e.g., brightness) in a side viewing angle, and the color purity is increased by the second color particles 188.

Each of the first and second color filter pattern layers 182 and 186 may further include a binder resin, a photo-initiator, a monomer and an additive.

For example, the binder resin may include at least one of a cardo-based binder resin, an acrylic-based binder resin, a polyimide-based binder resin, and a polyurethane-based binder resin. The photo-initiator may include at least one of an oxime-ester-based compound, a triazine-based compound, and an acetophenone-based compound.

The monomer may include at least one selected from the group consisting of ethylene glycol diacrylate, triethylene glycol diacrylate, 1,4-butanediol diacrylate, 1,6-hexanediol diacrylate, neopentyl glycol diacrylate, pentaerythritol acrylate, pentaerythritol diacrylate, pentaerythritol triacrylate, dipentaerythritol diacrylate, dipentaerythritol triacrylate, dipentaerythritol pentaacrylate, dipentaerythritol hexaacrylate, bisphenol A diacrylate, trimethylolpropane triacrylate, novolac epoxy acrylate, ethylene glycol dimethacrylate, diethylene glycol dimethacrylate, triethylene glycol dimethacrylate, propylene glycol dimethacrylate, 1,4-butanediol dimethacrylate, and 1,6-hexanediol dimethacrylate, but is not limited thereto. The additive may include at least one of a silane coupling agent and a surfactant, but is not limited thereto.

The organic light emitting display device 100 includes the color filter layer 180 so that an external light reflection can be minimized. The organic light emitting display device 100 includes the color filter layer 180 without a polarization plate so that the external light reflection can be minimized while minimizing the luminance decrease.

A second protection layer 178 is disposed on the black matrix 176 and the color filter pattern layers 182 and 186 and over an entire surface of the substrate 102. The second protection layer 178 may be formed of an inorganic insulating material, e.g., silicon oxide or silicon nitride or an organic insulating material, e.g., photo-acryl or benzocyclobutene, and may have a single-layered structure or a multi-layered structure.

In the first embodiment of the organic light emitting display device 100 of the present disclosure, since the color filter layer 180 includes the first color filter pattern layer 182 including the first color particles 184 with the first size and the second color filter pattern layer 186 includes the second color particles 188 with the second size, which is smaller than the first size, external light reflection can be minimized without a polarization plate, and the luminance at a side viewing angle can be improved.

However, since the first color filter pattern layer 182 including the first color particles 184, which are larger than the second color particles 188 in the second color filter pattern layer 186, is disposed to be closer to the OLED D than is second color filter pattern layer 186, the light from the OLED D may be scattered by the first color particles 184. As a result, the luminance of the organic light emitting display device 100 may be decreased. For example, the light from the OLED D may be scattered by the first color particle 184 and absorbed in the black matrix 176 so that the luminance of the organic light emitting display device 100 may be decreased.

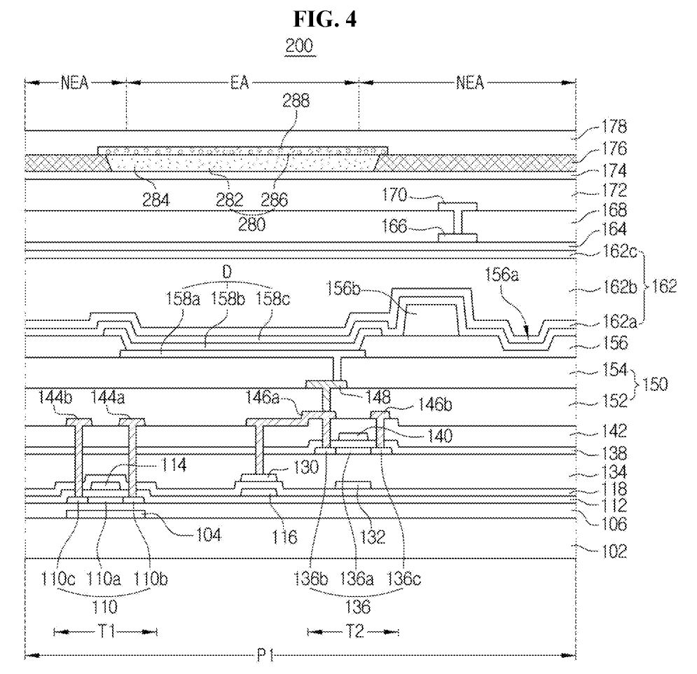

FIG. 4 is a schematic cross-sectional view illustrating an organic light emitting display device according to a second embodiment of the present disclosure.

As shown in FIG. 4, the organic light emitting display device 200 includes a substrate 102, a planarization layer 150 on the substrate 102, an OLED D on the planarization layer 150, a third buffer layer 174 on the OLED D, a black matrix 176 disposed on the third buffer layer 174 and corresponding to a non-emission area NEA and a color filter layer 280 disposed on the third buffer layer 174 and corresponding to an emission area EA.

The organic light emitting display device 200 according to the second embodiment of the present disclosure has a difference in the color filter layer 280 in comparison to the organic light emitting display device 100 according to the first embodiment of the present disclosure. The explanation is focused on the color filter layer 280.

The color filter layer 280 includes a first color filter pattern layer 282 and a second color filter pattern layer 286 on the first color filter pattern layer 282. Thus, the color filter layer 280 may have a double-layered structure.

The first color filter pattern layer 282 includes a first color particle 284 having a first size (e.g., a diameter), and the second color filter pattern layer 286 includes a second color particle 288 having a second size that is greater than the first size. The first size may be in a range of from 1nm to 80nm, and the second size may be in a range of from 80nm to 200nm. Each of the first and second color particles 284 and 288 may be a pigment. The first color filter pattern layer 282 is positioned between the OLED D and the second color filter pattern layer 286. Namely, the first color filter pattern layer 282 is disposed to be closer to the OLED D than the second color filter pattern layer 286.

The color purity is increased by the first color particles 284, and external light is scattered by the second color particles 288 to minimize the external light reflection and increase luminance in a side viewing angle.

The first color filter pattern layer 282 including the first color particles 284, which are smaller than the second color particles 288 in the second color filter pattern layer 286, is disposed to be closer to the OLED D. Accordingly, although the light from the OLED D may be scattered by the second color particles 288, the light is not absorbed in the black matrix 176 so that the luminance in a side viewing angle is increased in comparison with that seen in the first embodiment.

On the other hand, because the second color filter pattern layer 286 includes scattering particles in the role of the second color particles 288, a black property in an off state is degraded.

The second color filter pattern layer 286 has an area greater than the first color filter pattern layer 282. When the area of the second color filter pattern layer 286 is smaller than that of the first color filter pattern layer 282, external light may be incident to the first color filter pattern layer 282 without scattering by the second color filter pattern layer 286 so that a problem, e.g., a current leakage in the TFT, may occur. In addition, the light from the OLED D may pass through a boundary between the black matrix 176 and the first color filter pattern layer 282 so that the color purity may be degraded. However, in the organic light emitting display device 100 of the present disclosure, since the second color filter pattern layer 286 has an area greater than the first color filter pattern layer 282 and completely covers the first color filter pattern layer 282, the above problems can be prevented.

For example, an area of the first color filter pattern layer 282 may be smaller than that of the second color filter pattern layer 286 and greater than that of the opening in the pixel definition layer 156.

A thickness of the first color filter pattern layer 282 may be greater than that of the second color filter pattern layer 286. When the thickness of the first color filter pattern layer 282 is smaller than that of the second color filter pattern layer 286, the color purity may be degraded.

A thickness of the first color filter pattern layer 282 may be equal to or greater than that of the black matrix 176. When the thickness of the first color filter pattern layer 282 is smaller than that of the black matrix 176, the light from the OLED D may be scattered by the second color particles 288 in the second color filter pattern layer 286 and absorbed in the black matrix 176.

In the organic light emitting display device 200 of the present disclosure, since the color filter layer 280 includes the first color filter pattern layer 282 including the first color particles 284 with the first size and the second color filter pattern layer 286 including the second color particles 288 with the second size, which is greater than the first size, external light reflection can be minimized without a polarization plate and the luminance in a side viewing angle can be improved.

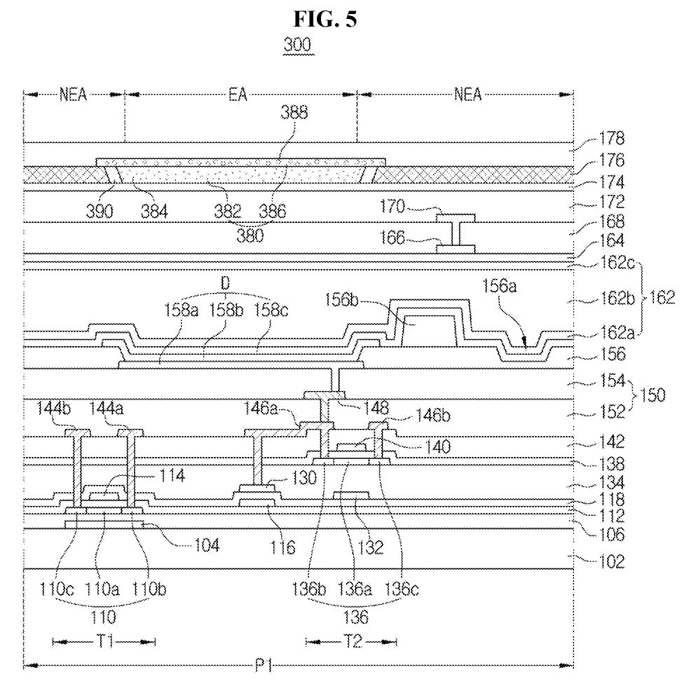

FIG. 5 is a schematic cross-sectional view illustrating an organic light emitting display device according to a third embodiment of the present disclosure.

As shown in FIG. 5, the organic light emitting display device 300 includes a substrate 102, a planarization layer 150 on the substrate 102, an OLED D on the planarization layer 150, a third buffer layer 174 on the OLED D, a black matrix 176 disposed on the third buffer layer 174 and corresponding to a non-emission area NEA, a scattering layer 390 at a side surface of the black matrix 176 and a color filter layer 380 disposed on the third buffer layer 174 and corresponding to an emission area EA.

The organic light emitting display device 300 according to the third embodiment of the present disclosure is distinguished by the scattering layer 390 and the color filter layer 380 in comparison to the organic light emitting display device 100 according to the first embodiment of the present disclosure. The explanation for the difference between the third and first/second embodiments is focused on the scattering layer 390 and the color filter layer 380.

The scattering layer 390 is disposed on the side surface of the black matrix 176, and also on the third buffer layer 174. For example, the scattering layer 390 of the display device 300 of the third embodiment may completely cover the side surface of the black matrix 176. A thickness of the scattering layer 390 along a dimension perpendicular to the plane of the substrate may be equal to the thickness of the black matrix 176. In other words, a height of the scattering layer 390 from the third buffer layer 174 may be equal to a height of the black matrix 176 from the third buffer layer 174.

The scattering layer 390 can include a scattering particle. The scattering particle may be transparent or white. The scattering particle may have a size (e.g., a diameter) in a range of 150nm to 300nm, e.g., 200nm to 300nm. For example, the scattering particle may be one of an inorganic nano-particle, e.g., TiO₂, ZnO, ZrO and SiO₂, a polymer nano-particle, e.g., a polystyrene bead or a poly(methyl methacrylate) (PMMA) bead, a porous nano-particle and a boron nitride (BN) particle. When the scattering particle is the BN particle, a scattering property and a heat-radiation property can be provided by the scattering layer 390.

The color filter layer 380 can include a first color filter pattern layer 382 and a second color filter pattern layer 386 on the first color filter pattern layer 382. Thus, the color filter layer 380 may have a double-layered structure.

The first color filter pattern layer 382 can include a first color particle 384 having a first size (e.g., a diameter), and the second color filter pattern layer 386 can include a second color particle 388 having a second size that is greater than the first size. The first size may be in a range of from 1nm to 80nm, and the second size may be in a range of from 80nm to 200nm. Each of the first and second color particles 384 and 388 may be a pigment. The first color filter pattern layer 382 can be positioned between the OLED D and the second color filter pattern layer 386. Namely, the first color filter pattern layer 382 can be disposed to be closer to the OLED D than the second color filter pattern layer 386.

The color purity can be increased by the first color particle 384, and external light is scattered by the second color particle 388 to minimize the external light reflection and increase luminance in a side viewing angle.

A size of the second color particles 388 may be equal to or smaller than that of the scattering particle. For example, when the scattering particles are larger than the second color particles 388, the light scattering at a side surface of the black matrix 176 is increased so that the luminance in a side viewing angle is further increased.

An area (e.g., a planar area) of the second color filter pattern layer 386 can be greater than that of the first color filter pattern layer 382 so that the second color filter pattern layer covers the scattering layer 390. When the second color filter pattern layer 386 does not cover the scattering layer 390, the light from OLED D may not pass the color filter layer 380 so that the color purity of the organic light emitting display device 300 may be degraded.

For example, an area of the first color filter pattern layer 382 may be smaller than that of the second color filter pattern layer 386 and greater than that of the opening in the pixel definition layer 156.

A thickness of the first color filter pattern layer 382 may be greater than that of the second color filter pattern layer 386. A thickness of the first color filter pattern layer 382 may be equal to or greater than that of the black matrix 176.

In the organic light emitting display device 300 of the present disclosure, since the color filter layer 380 includes the first color filter pattern layer 382 including the first color particles 384 with the first size and the second color filter pattern layer 386 including the second color particles 388 with the second size, which is greater than the first size, the external light reflection can be minimized without a polarization plate and the luminance in a side viewing angle can be thereby improved.

In addition, since the organic light emitting display device 300 includes the scattering layer 390 at a side surface of the black matrix 176, the luminance in a side viewing angle can be further improved.

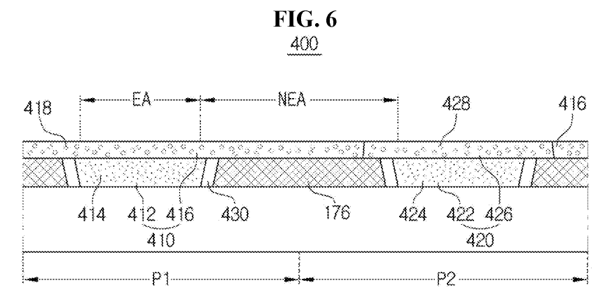

FIG. 6 is a schematic an organic light emitting view illustrating a light emitting display device according to a fourth embodiment of the present disclosure.

For convenience of explanation, FIG. 6 only shows a black matrix 176, a color filter layer 410, a second color filter layer 420 and a scattering layer 430.

Referring to FIG. 6 with FIG. 4, the organic light emitting display device 400 includes a substrate 102, a planarization layer 150 on the substrate 102, an OLED D on the planarization layer 150, a third buffer layer 174 on the OLED D, a black matrix 176 disposed on the third buffer layer 174 and corresponding to a non-emission area NEA, a scattering layer 430 at a side surface of the black matrix 176, a first color filter layer 410 disposed on the third buffer layer 174 and corresponding to an emission area EA of a first pixel region P1 and a second color filter layer 420 disposed on the third buffer layer 174 and corresponding to an emission area EA of a second pixel region P2.

For example, the first pixel region P1 may be a blue pixel region, and the second pixel region P2 may be a green pixel region or a red pixel region.

The black matrix 176 is positioned at a boundary of the first and second pixel regions P1 and P2 and covers the non-emission area NEA between the emission area EA of the first pixel region P1 and the emission area EA of the second pixel region P2.

The scattering layer 430 may completely cover the side surface of the black matrix 176. A thickness of the scattering layer 430 may be equal to a thickness of the black matrix 176.

The first color filter layer 410 in the first pixel region P1 can include a first color filter pattern layer 412 and a second color filter pattern layer 416 on the first color filter pattern layer 412. The second color filter layer 420 in the second pixel region P2 can include a third color filter pattern layer 422 and a fourth color filter pattern layer 426 on the third color filter pattern layer 422. Each of the first and second color filter layers 410 and 420 can have a double-layered structure.

The first color filter pattern layer 412 can include first color particles 414 having a first size (e.g., a diameter), and the second color filter pattern layer 416 can include second color particles 418 having a second size that is greater than the first size. The third color filter pattern layer 422 can include a third color particle 424 having a third size, and the fourth color filter pattern layer 426 can include a fourth color particle 428 having a fourth size that is greater than the third size.

Each of the first and third sizes may be in a range of from 1nm to 80nm, and each of the second and fourth sizes may be in a range of from 80nm to 200nm. Each of the first to fourth color particles 414, 418, 424, 428 may be a pigment.

The first color filter pattern layer 412 can be positioned between the OLED D and the second color filter pattern layer 416. Thus, the first color filter pattern layer 412 can be disposed to be closer to the OLED D than the second color filter pattern layer 416. The third color filter pattern layer 422 can be positioned between the OLED D and the fourth color filter pattern layer 426. Thus, the third color filter pattern layer 422 can be disposed to be closer to the OLED D than the fourth color filter pattern 426.

An area of the second color filter pattern layer 416 may be greater than that of the first color filter pattern layer 412 so that it covers the scattering layer 430. An area of the fourth color filter pattern layer 426 may be greater than that of the third color filter pattern layer 422 so that it covers the scattering layer 430.

The second color filter pattern layer 416 in the first pixel region P1 may extend into a portion of the second pixel region P2 to cover at least a portion of the non-emission area NEA of the second pixel region P2. The black matrix 176 has a relatively low absorption rate for long-wavelength visible light. Accordingly, external light reflection may be increased, and the external light may pass through the black matrix 176 and be incident on the semiconductor layer of the TFT. However, in the organic light emitting display device 400 according to an embodiment of the present invention, since the second color filter pattern layer 416, e.g., a blue color filter pattern, covers the black matrix 176, the latter problem can be prevented.

For example, when the emission area EA of the first pixel region P1 and the emission area EA of the second pixel region P2 have substantially the same area (e.g., planar area), the first and third color filter pattern layers 412 and 422 have substantially the same area, while the second color filter pattern layer 416 may have an area that is larger than the fourth color filter pattern layer 426.

In the organic light emitting display device 400 of the present disclosure, the first color filter layer 410 includes the first color filter pattern layer 412 including first color particles 414 with the first size and the second color filter pattern layer 416 including second color particles 418 with the second size, which is greater than the first size, and the second color filter layer 420 includes the third color filter pattern layer 422 including third color particles 424 with the third size and the fourth color filter pattern layer 426 including fourth color particles 428 with the fourth size, which is greater than the third size. Accordingly, the external light reflection can be minimized without a polarization plate and the luminance in a side viewing angle can be improved.

In addition, since the organic light emitting display device 400 includes the scattering layer 430 at a side surface of the black matrix 176, the luminance in a side viewing angle can be further improved.

Moreover, in the organic light emitting display device 400, the second color filter pattern layer 416 extends to cover the black matrix 176, and the relatively low absorption with respect to long-wavelength visible light can be compensated.

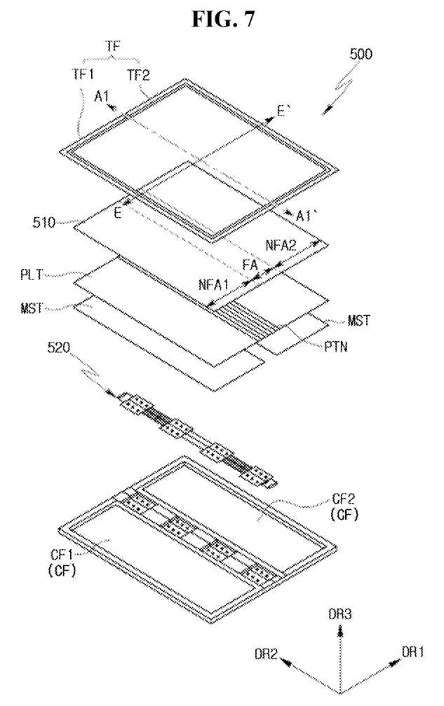

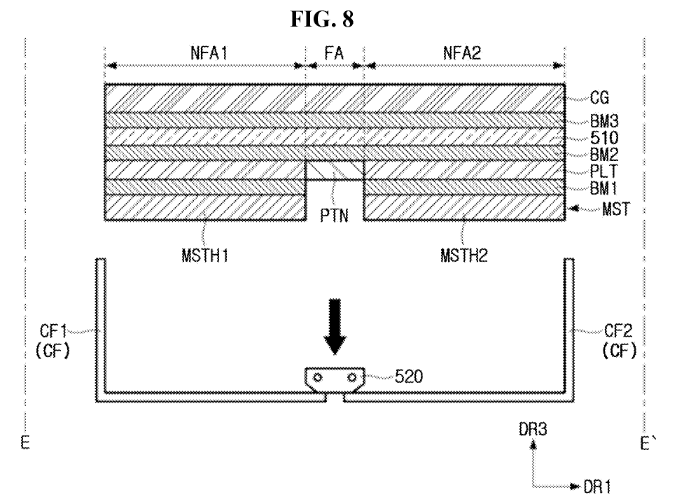

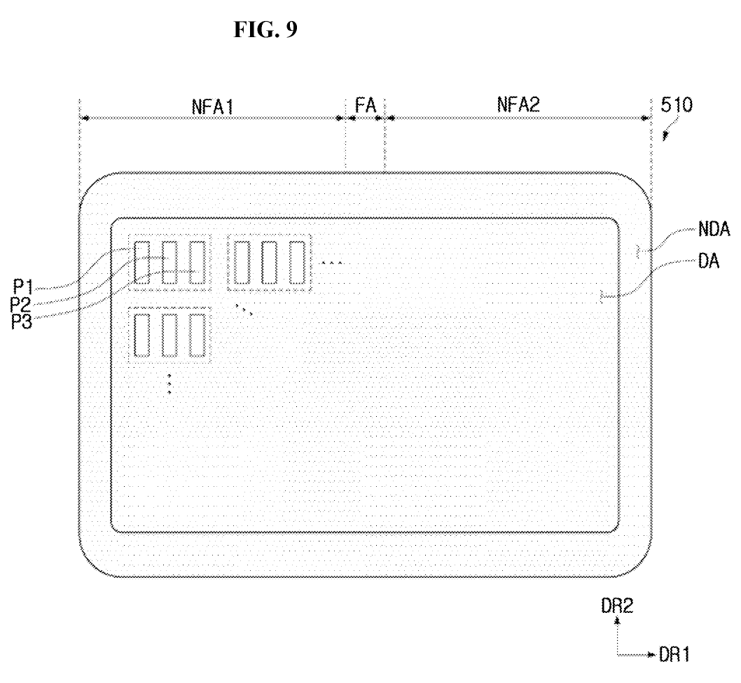

FIG. 7 is a schematic exploded perspective view of a display module according to an embodiment of the present disclosure. FIG. 8 is a schematic cross-sectional view of a display module according to an embodiment of the present disclosure. FIG. 9 is a schematic plan view of a display module according to an embodiment of the present disclosure. FIG. 8 shows a cross-sectional view taken along the line E-E’.

Referring to FIGS. 7 to 9, the display module 500 of the present disclosure may be a foldable display device module, and a folding axis A1-A1‘ of the display module 500 may be along a second direction DR2. A first direction DR1 may be perpendicular to the second directionDR2, and a third direction DR3 may be perpendicular to the first and second directions DR1 and DR2.

A top frame TF is disposed on the uppermost portion of the display module 500. With respect to the folding axis A1-A1’, the top frame TF includes the first top frame TF1 disposed at one side and the second top frame TF2 disposed at the other side. The top frame TF may be disposed to cover an edge of a display device 510. The top frame TF may protect the display device 510 from an external impact. The top frame TF may form a bezel of the display device 510.

A cover layer CG may be disposed under the top frame TF. The cover layer CG may be disposed above the display device 510.

The cover layer CG may be disposed above the display device 510 to protect members disposed under the cover layer CG from the outside.

An assembly is disposed under the cover layer CG. The assembly includes the display device 510 and a plate PLT. The display device 510 may have substantially the same structure as one of the display devices 100, 200, 300 and 400.

The plate PLT may be disposed under the display device 510 and may include various plates for supporting the display device 510. For example, the plate may include a back plate for supporting the display device 510, a top plate disposed under the back plate and formed of a stainless steel (SUS) material, a bottom plate disposed under the top plate and having a pattern formed on a folding portion, a heat dissipation sheet which functions as heat dissipation, a middle plate for covering an uneven plane due to various elements of the hinge assembly. The bottom plate may be formed of a SUS material.

A slit pattern PTN may be formed in the plate PLT. The slit pattern PTN may be formed at a position corresponding to the folding area FA of the display device 510. The slit pattern PTN may be a slit-shaped etched portion formed in the plate PLT. For example, the plate PLT may be formed of a metal, e.g., a SUS material. In this case, there may be a damage on the plate PLT in the folding operation and/or the unfolding operation. However, according to an embodiment of the present invention, the plate PLT includes the slit pattern PTN so that the above damage on the plate PLT can be prevented.

A middle plate MST is disposed under the assembly. The middle plate MST supports elements disposed thereabove. In addition, the hinge assembly 520 and the cover frame CF are disposed under the middle plate MST, and their upper surfaces may be uneven. The middle plate MST may flatten an uneven lower surface. The middle plate MST may be formed of a material, e.g., plastic, polyimide or metal, to increase the rigidity of the display module 500. For example, the middle plate MST may include aluminum or SUS, but it is not limited thereto.

The middle plate MST may include a first middle plate portion MSTH1 disposed in a first unfolding area NFA1, and a second middle plate portion MSTH2 disposed in a second unfolding area NFA2.

The hinge assembly 520 is disposed under the assembly. The hinge assembly 520 is disposed under the folding area FA. The hinge assembly 520 may have a shape extending in the folding axis A1-A1‘. The hinge assembly 520 may perform a folding motion in which one side and the other side rotate about the folding axis A1-A1‘.

The cover frame CF is disposed under the hinge assembly 520. An accommodation groove, in which a portion of the hinge assembly 520 may be disposed, may be formed in an upper surface of the cover frame CF. The cover frame CF includes the first cover frame CF1 disposed at one side of the folding axis A1-A1‘ and the second cover frame CF2 disposed at the other side of the folding axis A1-A1‘. The cover frame CF may be a housing for defining the side and back surfaces of the display module 500. The cover frame CF may protect the display module 500 from an external impact. The cover frame CF may be coupled to the hinge assembly 520. The folding and unfolding of the display module 500 can be provided according to the rotation of the cover frames CF1 and CF2.

Coupling members BM1, BM2, and BM3 for coupling the adjacent members MST, PLT, PTN and CG may be further disposed between the adjacent members. In each of the unfolded areas NFA1 and NFA2, the first coupling member BM1 may couple the middle plate portions MSTH1 and MSTH2 with the plate PLT, and the second coupling member BM2 may couple the plates PLT and PTN with the display device 510. The third coupling member BM3 may couple the display device 510 with the cover layer CG.

The plate PLT, the middle plate portion MSTH1, and the middle plate portion MSTH2, which are coupled, may be seated on the cover frames CF1 and CF2. The display device 510 may perform folding and unfolding operations by the hinge assembly 520 disposed on the cover frames CF1 and CF2.

The plate PLT and the middle plate MST, which are coupled to each other, may be disposed on the cover frames CF1 and CF2. The display module 500 can be folded and unfolded by the hinge assembly 520 disposed in the cover frames CF1 and CF2.

The display device 510 may include a display area DA and a non-display area NDA outside the display area DA. The non-display area NDA may surround the display area DA. In the display area DA, a plurality of pixel regions P1, P2 and P3 are arranged.

The display device 510 may include a folding area FA and a first unfolding area NFA1 at one side of the folding area FA and a second unfolding area NFA2 at the other side of the folding area FA.

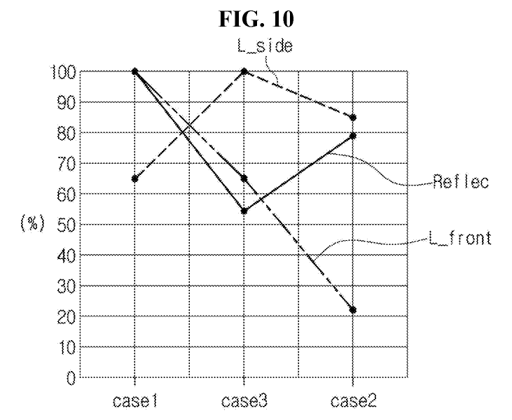

FIG. 10 is a graph showing a reflectance, a luminance in a front viewing angle and a luminance in a side viewing angle.

The “Case1” shows a simulation data of the reflectance, the luminance in a front viewing angle and the luminance in a side viewing angle of an organic light emitting display device including a color filter layer with a relatively small color particle (about 50nm diameter) and a single-layered structure. The “Case2” shows a simulation data of the reflectance, the luminance in a front viewing angle and the luminance in a side viewing angle of an organic light emitting display device including a color filter layer with a relatively large color particle (about 100nm diameter) and a single-layered structure.

The “Case3” shows a simulation data of the reflectance, the luminance in a front viewing angle and the luminance in a side viewing angle of an organic light emitting display device including a first color filter layer (a lower color filter layer) with a relatively small color particle (about 50nm diameter) and a second color filter layer (an upper color filter layer) with a relatively large color particle (about 100nm diameter). The color filter layer in the “Case3” has a double-layered structure.

As shown in FIG. 10, as the size of the color particle is increased, the scattering property is increased. As a result, the luminance in the front viewing angle “L_front” and the reflectance “Reflec” are decreased, and the luminance in the side viewing angle “L_side” is increased. Accordingly, the luminance in the front viewing angle “L_front”, the reflectance “Reflec” and the luminance in the side viewing angle “L_side” are in a trade-off relationship.

However, in the organic light emitting display device of “Case3”, where the color filter layer includes the lower color filter pattern including a relatively small color particle and the upper color filter pattern including a relatively large color particle, the reflectance is significantly decreased, and the luminance in the side viewing angle is significantly increased.

When the small color particle and the large color particle are mixed in the color filter layer having a single-layered structure, the luminance in the front viewing angle and the reflectance and the luminance in the side viewing angle are in a trade-off relationship. However, in the organic light emitting display device, where the color filter layer includes the lower color filter pattern including a relatively small color particle and the upper color filter pattern including a relatively large color particle, the luminance in the front viewing angle, the reflectance and the luminance in the side viewing angle are free from a trade-off relationship.

Accordingly, in the display device according to an embodiment of the present disclosure, a low reflectance and an improved luminance observed at a side viewing angle can be realized while minimizing a decrease in luminance observed at a frontal viewing angle.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device, comprising:
a substrate including a pixel region, the pixel region including an emission area and a non-emission area;
a planarization layer covering the substrate;
a light emitting diode on the planarization layer and in the pixel region;
a buffer layer on the light emitting diode;
a black matrix disposed on the buffer layer and corresponding to the non-emission area; and
a color filter layer disposed on the buffer layer and corresponding to the emission area, the color filter layer including a first color filter pattern layer and a second color filter pattern layer on the first color filter pattern layer,
wherein one of the first and second color filter pattern layers includes a first color particle having a first size, and the other one of the first and second color filter pattern layers includes a second color particle having a second size, and
wherein the second size is greater than the first size.

2. The display device according to claim 1, wherein the first size is in a range of about 1 nm to about 80 nm, and the second size in a range of about 80 nm to about 200 nm.

3. The display device according to claim 1, wherein the second color filter pattern layer includes the second color particle.

4. The display device according to claim 1, further comprising:
a scattering layer that includes a scattering particle and is disposed on a side surface of the black matrix and on the buffer layer.

5. The display device according to claim 4, wherein the scattering particle has a third size that is equal to or greater than the second size.

6. The display device according to claim 5, wherein the third size is in a range of about 200 nm to about 300 nm.

7. The display device according to claim 5, wherein the second color filter pattern layer covers the scattering layer.

8. The display device according to claim 1, wherein the first color filter pattern layer has a first thickness, and the second color filter pattern layer has a second thickness that is smaller than the first thickness.

9. The display device according to claim 8, wherein the first thickness of the first color filter pattern layer is equal to or greater than a thickness of the black matrix.

10. The display device according to claim 1, wherein the second color filter pattern layer has an area that is larger than that of the first color filter pattern layer.

11. The display device according to claim 10, wherein the second color filter pattern layer covers the black matrix.

12. The display device according to claim 1, wherein the pixel region includes a first pixel region and a second pixel region that is adjacent to the first pixel region, and
wherein the second color filter pattern layer in the first pixel region extends into the non-emission area of the second pixel region.

13. The display device according to claim 12, wherein the second color filter pattern layer in the first pixel region has a blue color filter pattern.

14. The display device according to claim 12, wherein the second color filter pattern layer in the first pixel region covers at least a portion of the black matrix in the non-emission area of the second pixel region.

15. The display device according to claim 12, wherein an area of the first color filter pattern layer in the first pixel region is the same as an area of the first color filter pattern layer in the second pixel region, and
wherein an area of the second color filter pattern layer in the first pixel region is greater than an area of the second color filter pattern layer in the second pixel region.

16. The display device according to claim 1, further comprising:
a pixel definition layer disposed on the planarization layer and corresponding to the non-emission area,
wherein the pixel definition layer has a light-absorbing property.

17. The display device according to claim 16, wherein the pixel definition layer includes an opening in correspondence to the emission area,
wherein an area of the color filter layer is greater than an area of the opening.

18. The display device according to claim 1, further comprising:
a first thin film transistor disposed between the substrate and the planarization layer and including a first semiconductor layer; and
a second thin film transistor disposed between the substrate and the planarization layer and including a second semiconductor layer.

19. The display device according to claim 18, wherein the first semiconductor layer comprises an oxide semiconductor material.

20. The display device according to claim 19, wherein the first thin film transistor is a driving thin film transistor electrically connected to the light emitting diode.

21. A color filter for modifying light emitted from a monochromatic light source, the color filter comprising:
a first particle layer including pigment particles in a first size range; and
a second particle layer including pigment particles in a second size range,
wherein:
the second particle layer is on the first particle layer;
the first size range is substantially different from the second size range;
the first size range does not fully include the second size range; and
the second size range does not fully include the first size range.

22. The color filter of claim 21, wherein the particles in the first size range are larger than the particles in the second size range.

23. The color filter of claim 21, wherein the particles in the first size range are smaller than the particles in the second size range.

24. The color filter of claim 23, further comprising a plurality of color filter areas that are detached from each other, the plurality of color filter areas corresponding to a parallel plurality of light emitting areas, the plurality of light emitting areas each being configured to emit monochromatic light of the same color.

25. The color filter of claim 24, wherein the first size range is from about 1 nm to about 80 nm, and the second size range is from about 80 nm to about 200 nm.

26. A color filter system comprising three color filters according to claim 24, wherein each color filter is configured to modify monochromatic light having a wavelength different from the wavelengths of monochromatic light modified by the other color filters.

27. The color filter system of claim 26, wherein the three color filters modify red, green and blue wavelengths of light, respectively.

28. The color filter system of claim 27, wherein each color filter area of a color filter is disposed adjacent to a color filter area of each of the other two color filters, forming a color display area of a display device.

29. The color filter system of claim 28, wherein a layer of transparent or white scattering particles is disposed in contact with an edge of each color filter area.
